(19) United States
(12) Patent Application Publication
(10) Pub. No.: US 2023/0053615 A1
(43) Pub. Date: Feb. 23, 2023

(54) GENERATION OF A BUILDING INFORMATION MODEL

(71) Applicant: Siemens Schweiz AG, Zurich (CH)

(72) Inventors: Veronica Liebig, Munchen (DE); Hermann Georg Mayer, Prien am Chiemsee (DE)

(21) Appl. No.: 17/879,942

(22) Filed: Aug. 3, 2022

(30) Foreign Application Priority Data
Aug. 18, 2021 (EP) 21191900.6

(51) Int. Cl. G06F 30/13

(52) U.S. Cl. CPC G06F 30/13

(57) ABSTRACT

A method and a system for generating a building information model, in particular a BIM model, in order to work on the building, such as in the case of restoration work, for example. A two-dimensional, digitized building plan of the building is read in, wherein the building plan includes building objects and building object data assigned to the building objects. A scanning unit is used to acquire three-dimensional building data that are compared with the building plan. A building object in the building plan is detected based on the comparison data and the building object data of the building object are output. The building information model is generated from the three-dimensional building data and the detected building object and the building object data thereof are integrated into the building information model. The building information model is output for working on the building.

### CROSS-REFERENCE TO RELATED APPLICATIONS

This application claims priority to EP Application No. 21191900.6, having a filing date of Aug. 18, 2021, the entire contents of which are hereby incorporated by reference.

### FIELD OF TECHNOLOGY

The following relates to a method and to a system for generating a building information model and also to a computer program product suitable for carrying out the steps of the method.

### BACKGROUND

In the construction industry, there is a great need for digitization for existing buildings. However, for these existing buildings, there is often neither what is known as a BIM model, where “BIM” stands for “Building Information Modeling” and may also be referred to as building information model, nor another digital 3D model. These would be helpful, for example, with respect to upcoming renovation and restoration works on a building. Using a BIM model and corresponding BIM software, it is possible to carry out BIM processes such as material estimations, statistical analyses and other analyses using tools provided by third parties, such as evacuation route simulations, for example.

Instead, there are often only two-dimensional plans (2D plans) available, from which three-dimensional models (3D models) can be generated. These 3D models can be supplemented with formal object descriptions, such as doors and windows, by means of object recognition. However, the problem of changes in the buildings, such as removal of a wall for example, not being documented in the original 2D plan may arise in this method. The result thereof is a 3D model that does not depict the current state of the physical building.

As an alternative to this model, it is also possible to generate a 3D point cloud model of a building by means of a laser scan. In this method, it is ensured that the 3D model corresponds to the current state of the building. The disadvantage of this method is that a large number of pieces of information, such as the thickness or the material of a wall for example, is not included in the scanned surface and has to be input into the building model retrospectively. This adjustment of the generated building model is generally time-consuming and may be susceptible to errors, since information has to be exchanged via several interfaces and/or people from different trade companies. When a 3D model is generated from a point cloud from a 3D scan, the rooms of a building are scanned one after another using a laser. In this case, when the individual rooms are combined in the overall model of the building, inaccuracies may also arise because the point cloud illustration of an identical wall, scanned from two sides, cannot be referenced sufficiently. Using the principle of room recognition, it is often possible to locate the capture region, based on the specific room geometry thereof, in the overall plan sufficiently well. However, in the case of buildings with a large number of identical rooms (such as hotels or office complexes for example), the method reaches its limits because in this case the rooms cannot be clearly distinguished (in a rule-based or data-based manner) based on typical objects and additionally the geopositon has to be tracked in order to connect the rooms to one another correctly in the 3D model.

### SUMMARY

An aspect relates to improve the generation of a 3D building information model for a building.

According to a first aspect, embodiments of the invention relate to a method for generating a building information model for working on a building, comprising the following method steps:

a) reading in a two-dimensional, digitized building plan of the building, wherein the building plan comprises building objects and building object data assigned to the building objects,

b) acquiring three-dimensional building data of at least a part of the building by means of a scanning unit,

c) comparing the three-dimensional building data with the building plan, wherein at least a subregion of the building plan at a position of the scanning unit is evaluated, and outputting comparison data,

d) detecting at least one building object in the building plan based on the comparison data and outputting building object data assigned to the detected building object,

e) generating the building information model from the three-dimensional building data,

f) integrating the detected building object and the assigned building object data into the building information model, and

g) outputting the generated building information model in order to work on the building.

The method may be in particular at least partly computer-aided or computer-implemented, with for example an implementation of the method in which in particular a processor performs at least one method step of the method being understood. A processor in the context of embodiments of the invention may be understood to mean for example a machine or an electronic circuit. A processor may in particular be a main processor (central processing unit, CPU), a microprocessor or a microcontroller, for example an application-specific integrated circuit or a digital signal processor, possibly in combination with a memory unit for storing program commands, etc. A processor may also for example be an IC (integrated circuit), in particular an FPGA (field-programmable gate array) or an ASIC (application-specific integrated circuit), or a DSP (digital signal processor) or a graphics processor GPU (graphics processing unit). A processor may also be understood to mean a virtualized processor, a virtual machine or a soft CPU. It may also be for example a programmable processor that is equipped with configuration steps for performing said method according to embodiments of the invention or is configured with configuration steps such that the programmable processor performs the inventive features of the method, the component, the modules, or other aspects and/or sub-aspects of embodiments of the invention.

Unless stated otherwise in the following description, the terms “carry out”, “calculate”, “computer-aided”, “compute”, “determine”, “generate”, “configure”, “reconstruct” and the like relate to operations and/or processes and/or processing steps that change and/or generate data and/or convert data into other data, wherein the data may be represented or be present in particular in the form of physical variables, for example in the form of electrical pulses. The expression “computer” should in particular be interpreted as broadly as possible in order in particular to cover all electronic devices having data processing properties. Computers may thus for example be personal computers, servers, programmable logic controllers (PLC), hand-held computer systems, pocket PC devices, mobile radio devices and other communication devices that are able to process data in a computer-aided manner, processors and other electronic data processing devices.

“Provide”, in particular with reference to data and/or information, in the context of embodiments of the invention may be understood to mean for example a computer-aided provision. By way of example, provision is implemented by means of an interface, such as for example a network interface, a communication interface or an interface to a memory unit. Within the scope of the provision for example, corresponding data and/or information can be transmitted and/or sent and/or retrieved and/or received via an interface of this kind.

In connection with embodiments of the invention, a “building information model” can be understood to mean a (3D) BIM model or building information modeling model. A building information model comprises in particular building data in three dimensions (3D). In particular, all relevant building data are modeled, combined and acquired digitally. Furthermore, a building information model can also comprise information such as information about construction materials, for example.

A “scanning unit” can be understood to mean a scanner or laser scanner, for example. Using the scanning unit, the building or parts of the building can be scanned in three dimensions in a Cartesian coordinate system, that is to say data or building data can be measured/taken. The scanning unit thus provides in particular three-dimensional (3D) building data. By way of example, the three-dimensional building data can be output as points or as point clouds, that is to say individual measurement data are assigned to those three-dimensional coordinates respectively. “Building data” can also be understood to mean for example surfaces, corners, walls, shapes, etc. that can be acquired by means of a scanning unit/scanner.

It is an advantage of embodiments of the present invention that a building information model can be generated in a simple manner and with a low degree of computational outlay. In particular, the essential and otherwise complex processing step of object recognition is automated by virtue of information being extracted based on the point clouds of the 3D data and the building plan during the acquisition of the three-dimensional data and the resulting generation of the building information model. This reduces the outlay of the manual post-processing of the building information model/BIM model.

Embodiments of this invention thus make it possible to generate a 3D BIM model on the basis of a two-dimensional (2D) plan and a point cloud. If during the scan the generated point cloud is compared with various 2D plans, such as a floor plan, a wiring plan, etc., the corresponding formal information may already be incorporated into the BIM model or the detected differences may already be transferred to the plan. Such synchronization can be made possible for example by moving the scanner along a predefined trajectory. This tracking method has the advantage that the limited accuracy of the GPS signal inside the building no longer plays a role compared to the GPS-based localization.

The building information model generated in this way is provided for working on the building. “Working on the building” can be understood to mean in particular maintenance, restoration, renovation or similar of the building. It is also conceivable that the building model is used, for example, for further analyses, such as the building statics, for example, or for a computer-aided simulation of a process in the building, such as a people flow simulation, for example.

In an advantageous embodiment of the method, the three-dimensional building data can be acquired by scanning the building along a trajectory defined in the building plan by means of the scanning unit.

This facilitates the comparison or synchronization of the 3D building data with the 2D building plan, for example.

In an advantageous embodiment of the method, a starting point can be determined based on the building plan and the three-dimensional building data can be acquired proceeding from this starting point.

As a result, for example the referencing of the building plan and of the three-dimensional data is improved. By way of example, the building data can be acquired, proceeding from the starting point, along a trajectory stipulated based on the building plan, with the scanning unit acquiring the building data along the trajectory.

In one embodiment of the method, method steps b) to d), that is to say the method steps of acquisition, comparison and detection, can be repeated after predefined time steps.

In an alternative embodiment of the method, method steps b) to d), that is to say the method steps of acquisition, comparison and detection, can be repeated after detection of a building object.

The building information model can be created substantially during the scan by way of the iterative procedure.

In another embodiment of the method, a deviation of the three-dimensional building data from the building plan can be detected based on the comparison data.

By comparing the current, measured building data with the structures in the building plan, it is possible to rapidly detect changes in the building, such as a missing or added wall, for example. By way of example, a signal or a warning can be output when a deviation has been detected.

In another embodiment of the method, if a deviation is identified, a building object and corresponding building object data can be generated depending on the three-dimensional building data and integrated into the building information model.

Building object data that reproduce the three-dimensional building data are generated. In this way, the building information model can be supplemented with additional information based on the 3D data.

In another embodiment of the method, the method step of comparing the three-dimensional building data with the building plan can comprise the following substeps:
determining a horizontal structure based on the three-dimensional building data,
generating a first line based on the horizontal structure,
comparing the first line with lines of the building plan, wherein the first line is assigned to a second line of the building plan, and
correcting the spatial coordinates of the three-dimensional building data, assigned to the first line, depending on the position of the second line.

This increases in particular the accuracy of the building information model, in particular in the wall region or in corners.

In another embodiment of the method, the at least one building object can be detected based on the second line in the building plan.

By way of example, the first and the second line can be aligned, for example can be correlated, and the building object assigned to the second line can thus be determined.

In another embodiment of the method, the horizontal structure can be detected based on the three-dimensional building data by virtue of data points lying one above the other in the vertical direction being counted and being connected horizontally to adjacent data points along the respectively topmost data point provided that the adjacent data points in the vertical direction have a substantially corresponding number.

This procedure is based on the assumption that most structures in a building are generally perpendicular to ground level. This permits automated detection of building objects based on the three-dimensional building data. The extent in the z direction/vertical direction can be determined based on the three-dimensional building data.

In an alternative embodiment of the method, the method step of comparing the three-dimensional building data with the building plan can be carried out by means of a machine learning model trained for this purpose.

A machine learning model may be a neural network, for example. The machine learning model is trained by means of training data, for example, to compare a three-dimensional structure with a two-dimensional structure in a building plan. The training data can comprise for example three-dimensional building data as input data and two-dimensional data of building plans as output data for this purpose. The machine learning model is then trained to assign the input data to the output data and/or to output a notification when there is no correlation. The trained machine learning model can then be provided.

In one embodiment of the method, the building plan may be a floor plan or an electrical installation plan.

In one embodiment of the method, the building information model may be a BIM model.

According to a second aspect, embodiments of the invention relate to a system for generating a building information model for working on a building, comprising:
an interface that is set up in such a way as to to read in a two-dimensional building plan of the building, wherein the two-dimensional building plan comprises building objects and building object data assigned to the building objects,
a scanning unit that is set up in such a way as to acquire three-dimensional building data of at least a part of the building,
a comparison unit that is set up in such a way as to compare the three-dimensional building data with the building plan, wherein at least a subregion of the building plan at the position of the scanning unit is evaluated, and to output comparison data,
a detection unit that is set up in such a way as to detect at least one building object in the building plan based on the comparison data and to output building object data assigned to the detected building object,
a model generator that is set up in such a way as to generate the building information model from the three-dimensional building data,
an integration unit that is set up in such a way as to integrate the detected building object and the assigned building object data into the building information model, and
an output unit that is set up in such a way as to output the generated building information model in order to work on the building.

Embodiments of the invention furthermore relate to a computer program product (non-transitory computer readable storage medium having instructions, which when executed by a processor, perform actions) which can be loaded directly into a programmable computer, comprising program code parts which, when the program is executed by a computer, cause the computer to carry out the steps of a method according to embodiments of the invention.

A computer program product may be provided or supplied for example on a storage medium such as for example a memory card, USB stick, CD-ROM, DCD, a non-transitory storage medium or else may be provided or supplied in the form of a downloadable file from a server in a network.

### BRIEF DESCRIPTION

Some of the embodiments will be described in detail, with reference to the following figures, wherein like designations denote like members, wherein:

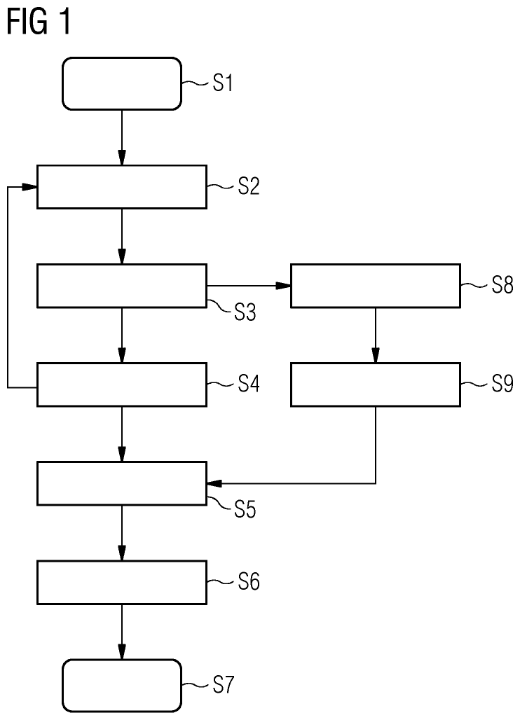

FIG. 1: shows a flowchart of a first exemplary embodiment of the method for generating a building information model;

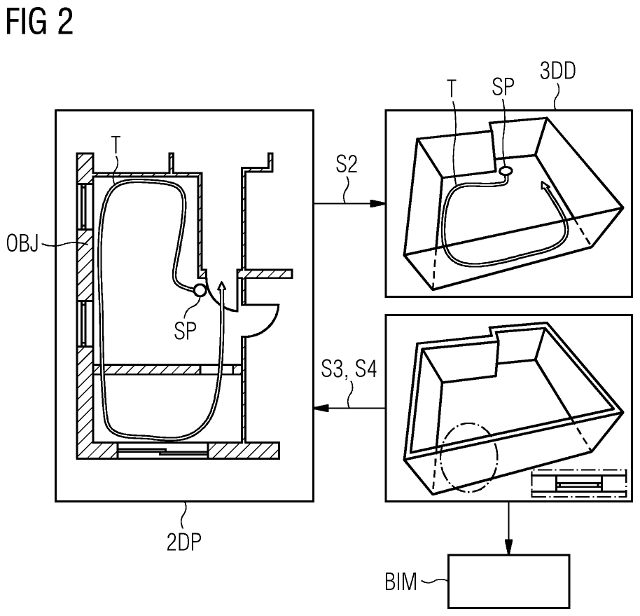

FIG. 2: shows a schematic illustration of a second exemplary embodiment of the method for generating a building information model;

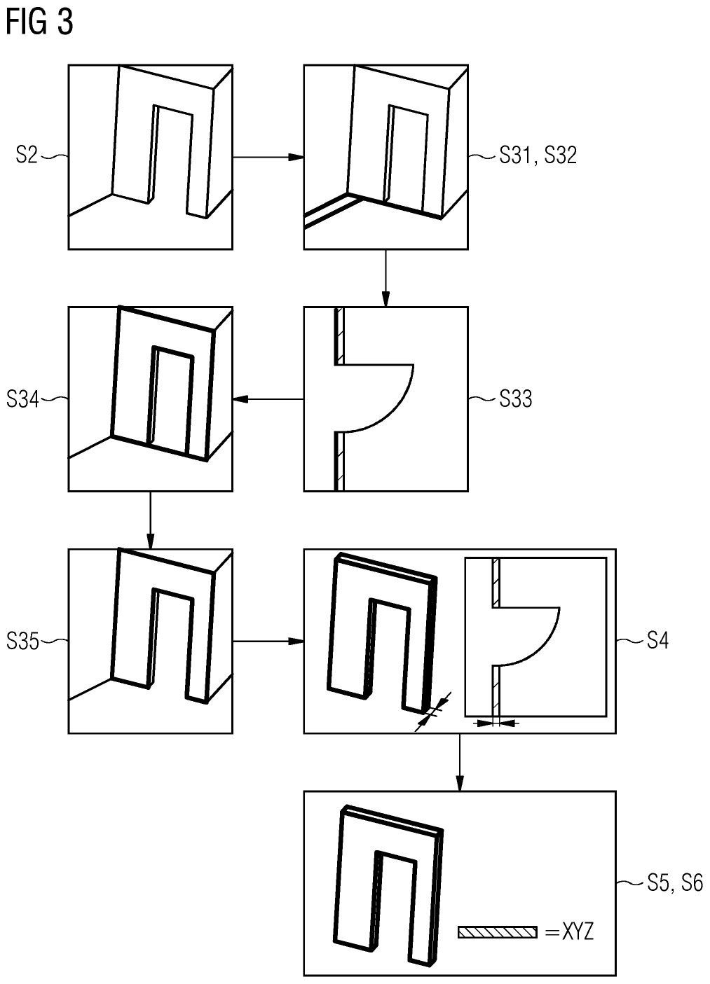

FIG. 3: shows a schematic illustration of a third exemplary embodiment of the method for generating a building information model;

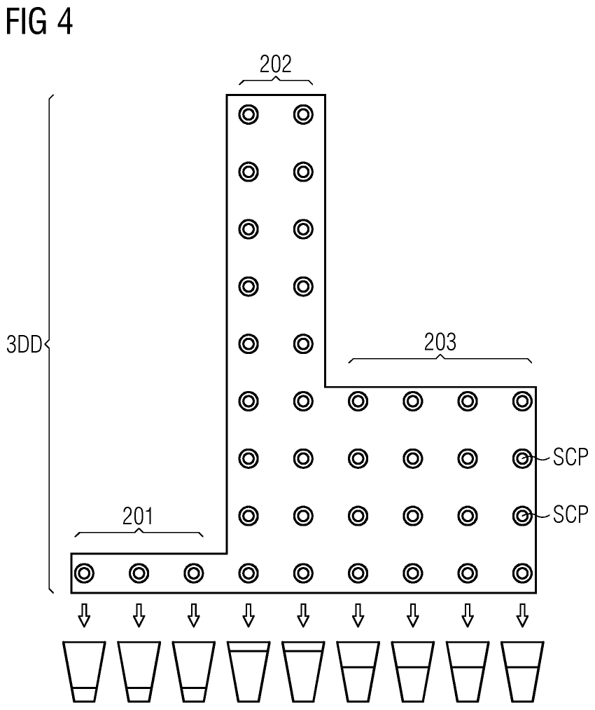

FIG. 4: shows a schematic illustration of an aspect of the method for generating a building information model; and

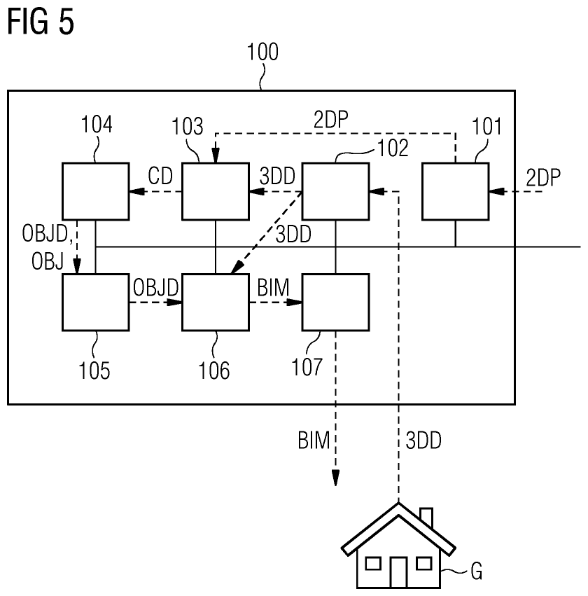

FIG. 5: shows a schematic illustration of a system for generating a building information model.

Parts corresponding to one another are provided with the same reference signs in all of the figures.

### DETAILED DESCRIPTION

In particular, the exemplary embodiments that follow merely show illustrative realization possibilities, how in particular such realizations of the teaching according to embodiments of the invention could be manifested, since it is impossible and also not helpful or necessary for the understanding of embodiments of the invention to name all these realization possibilities.

FIG. 1 shows a flowchart of a first exemplary embodiment of a method according to embodiments of the invention for generating a building information model that can be used for working on a building, for example. The flowchart shows the method steps of the method.

The method may be in particular at least partly computer-implemented. Said method comprises the following method steps:

In the first step S1 of the method, a two-dimensional, digitized building plan of the building is read in. The building plan may be for example a floor plan or an electrical installation plan. The building plan comprises building objects and building object data assigned to the building objects. By way of example, a floor plan includes positions or measurements regarding walls, doors, windows, etc. By way of example, an electrical installation plan includes a position, type of socket, switch etc.

In the next step S2 of the method, at least a part, such as for example a room, of the building is scanned by means of a scanning unit, such as for example a laser scanner, and corresponding three-dimensional building data are output. The three-dimensional building data may be present as point clouds, for example. A starting point for the laser scanner for such a room scan is stipulated based on the building plan. The room scan can be carried out proceeding from this starting point along a trajectory predefined in the building plan, that is to say the scanner moves along the predefined trajectory and in the process scans the building.

In the next step S3, the three-dimensional building data are compared with the building plan, wherein at least a subregion of the building plan at a position of the scanning unit is evaluated, and resulting comparison data are output. Comparison data can be understood as the result of the comparison, for example. The comparison data may include for example a correlation or a deviation of the three-dimensional building data with or from the building plan. In particular, this method step can be carried out by means of a machine learning method trained for this purpose, with the machine learning model being trained to output comparison data depending on three-dimensional building data and the two-dimensional building plan. In this case, comparison data may include for example a probability indication of a correlation of the 3D data with the 2D plan.

In the next method step S4, at least one building object is detected based on the comparison data, such as a wall, for example. The building object data of said detected building object, such as for example a wall thickness or a construction material, which are stored in the building plan, are then output.

Method steps S2 to S4 can be repeated iteratively in order for them to be carried out at the same time as the scanning of the building by means of the scanning unit.

As an alternative or in addition to step S4, in step S8, a deviation of the three-dimensional building data from the building plan can be detected based on the comparison data. In this case, in step S9, building object data can be generated depending on the three-dimensional building data. By way of example, a wall can be generated and corresponding three-dimensional data that represent a wall can be provided based on the three-dimensional data.

In the next step S5, the building information model is generated from the acquired three-dimensional building data. In this case, a three-dimensional, computer-aided model of the building or the scanned building region is first created.

Then, in step S6, the detected and/or the generated building object is integrated into the building information model. In other words, the building information model is supplemented in particular by the building object data.

In the next step S7, the generated building information model is output in order to work on the building, such as for example for maintenance, servicing, a structural change, etc. The building can then for example undergo maintenance, be restored, be changed, etc. by means of the building information model.

FIG. 2 shows a schematic illustration of another exemplary embodiment of the method according to embodiments of the invention for generating a building information model, such as for example a 3D BIM model, for at least a part of a building, such as for example a room.

A digitized, two-dimensional floor plan 2DP of a room of a building is shown. This can be used as the starting point for the method. By way of example, a starting point SP and a trajectory T for a laser scanner for scanning the room can be stipulated based on the floor plan 2DP. Three-dimensional building data of the room can be acquired S2 by means of the laser scanner proceeding from the starting point SP along the trajectory T. A three-dimensional building information model BIM of the room can be created from this three-dimensional building data. In particular, the point clouds generated from the scan can be compared with the floor plan during the scan.

Building objects OBJ can be ascertained and corresponding building objects can be output through iterative comparison S3 of the three-dimensional data with the building plan 2DP. Such synchronization can be made possible for example by moving the scanner along the predefined trajectory. This tracking method has the advantage in particular that the limited accuracy of a GPS signal inside the building no longer plays a role compared to the GPS-based localization.

For example, a wall OBJ can be detected in this way and a wall thickness can be ascertained based on the information in the building plan 2DP. The building object data, such as for example the wall thickness and/or a wall material, can be integrated into the building information model BIM. furthermore, deviations in the three-dimensional building data from the floor plan can be ascertained and corresponding information can be incorporated into the building information model BIM.

If during the scan the floor plan of a building is also considered at the same time, even standard objects OBJ such as doors, windows and/or sanitary facilities together with their standardized names and dimensions may thus be transferred to the building model BIM. It is thus not necessary for example for an integrated object recognition system in the scanning device to detect these standard elements. The computation resources that remain free can be used for example for identifying remaining building objects. As a result, the time required for the room scan can be reduced.

The floor plan provides further additional information regarding the walls. The walls can thus be identified during the scan. By simultaneously considering the floor plan, it is additionally possible to define the corresponding wall thicknesses and/or wall materials and the adjoining rooms in the model without access to the geodata of the scanner.

In addition to the scan of the room, a corresponding wiring diagram or an electrical installation plan can also be considered. In particular, in addition or as an alternative, the method can also be carried out using an electrical installation plan instead of a floor plan. The technical facilities of an existing building can also be characterized thereby. The individual facilities elements can be narrowed down using a product catalog and the stored building data, such as for example date of the installation of the corresponding building technology, manufacturer of the installed devices etc., more specifically according to device model/device type. For example, proposals for modernization measures can thus also be made, for example.

FIG. 3 shows a schematic illustration of another exemplary embodiment of the method according to embodiments of the invention for generating a building information model, such as for example a BIM model, for a building.

For the method, there is a two-dimensional building plan available in digitized/vectorized form, such as a 2D CAD plan, for example. if the building plan is only available in paper form or as a scan, first all lines and other primitives are vectorized, for which known methods exist.

In the vectorized building plan, a starting point for the method for generating the BIM model is optionally selected, the starting point also being found in the real environments, for example in a room of the building. The starting point has a locally unique, geometrically describable property, such as a corner point of the wall, for example. This property can also be retrieved for a scanner in the real environment. The stipulation of a starting point is advantageous in particular when the building has a large number of rooms, such as a hotel or a hospital, for example. the stipulation of a starting point may be omitted when the series of properties can be assigned clearly to one room in the plan. In this case, the starting point of the method can be found automatically, for example.

Proceeding from the starting point, the room is scanned along a predefined trajectory by means of the scanner until another unique feature or building object is identified in the scan and in the building plan, such as for example a corner of the room, a built-in unit, etc. The floor and the ceiling can be recorded in a similar way. The point cloud generated in this way from the scan can now be corrected based on the known structures from the 2D plan and a part is generated therefrom for a 3D BIM model (see below). The detected building object can then be set as a new starting point and the method is repeated, until the original starting point is reached. The method can be carried out online, that is to say during the scan, or offline in the course of a subsequent data evaluation.

In the method, there may not be any correlation between the currently scanned building area or building object and a next expected building object in the building plan. For example, this may be the case when changes have been made to the building that are not included in the 2D building plan. In such a case, appropriate 2D building objects can be generated. Building objects that match the current scan as well as possible are generated, that is to say ones that substantially correlate to the three-dimensional building data. Building objects that correspond to predefined proven patterns, such as for example that a wall is a flat surface that generally meets another wall at a 90° angle, are proposed. For example, such 2D building objects are present in a manner stored in a library. For example, a wall in the building plan can then be added to the building information mode in order to achieve correlation with the three-dimensional building data. If no building object that leads to a correlation can be added, the unprocessed point clouds can alternatively also be included in the generated building information mode or appropriately projected into the two-dimensional building plan.

The method for generating a 3D BIM model proceeding from a present two-dimensional building plan can be executed as follows:

First of all, a scanner is used to scan a section of the room of the building. Three-dimensional building data are output as the result of the scan. After the corresponding section of the room has been scanned, S2, lines representing the corresponding section in 2D CAD are generated from this section, S31, S32.

For this purpose, the three-dimensional building data are compared with the building plan, wherein at least a subregion of the building plan at a position of the scanning unit is evaluated. This comprises determining S31 a horizontal structure based on the three-dimensional building data. For this horizontal structure, a first line is generated S32. The method is based on the fact that structures in buildings, which are depicted in a 2D plan, are generally perpendicular to the surface.

The horizontal structure can be detected, for example, based on the three-dimensional building data by virtue of data points lying one above the other in the vertical direction being counted. Those topmost data points which are substantially, that is to say within a predefined inaccuracy, at the same height are then connected to one another horizontally. In other words, horizontal lines are formed from adjacent data points provided that the adjacent data points in the vertical direction have a number that corresponds substantially/within a predefined tolerance range. Data points can be combined so as to form a line which is as long as possible or another graphical primitive. For example, the respective topmost data points which form such a horizontal structure can be determined by counting the scan points.

The lines or primitives obtained in this manner are now compared S33 with the lines in the two-dimensional building plan, wherein a minimum distance between the line obtained and the structure of the building plan is determined. An optimized assignment is determined. In this case, the position of the scanner in the room or in the building plan can be taken into account, in particular.

The position of the three-dimensional building data or of the point cloud of the scan assigned to the first line can then be corrected S34. For example, the spatial coordinates of the three-dimensional building data, assigned to the first line, can be corrected depending on the position of the second line. In this case, the points belonging to the line, for example, can be shifted in the vertical or horizontal direction in such a manner that they correspond to the assigned line of the building plan. Position inaccuracies in the scan, for example at corners, can therefore be compensated for, for example. In addition, an image texture recorded by the scanner, for example a surface condition of a wall (for example brick wall), can be applied to the points. This information from the three-dimensional data may then likewise be included in the 3D BIM model (see below).

An extent of a detected building object in the z direction/vertical direction, which is not included in the 2D building plan, is taken S35 from the point cloud. This can be determined, for example, assuming that lines run parallel to the floor, with the result that corresponding data points in the vertical direction can be counted and converted into a height indication.

It is then possible to check S4 whether the line in the building plan that is assigned to the three-dimensional building data belongs to a superordinate structure or to a building object. In the example shown, the 2D line belongs to a polygon with hatching in the 2D plan, which, according to the hatching, describes a wall.

A 3D BIM model can be generated from the three-dimensional building data from the scan. The 3D BIM model can be output as a data structure, in particular. The 3D BIM model can be used to work on the building, for example for restoration or renovation.

The surface of the BIM object, for example brick structure of the wall element, obtained from the scan can be stored in the 3D BIM model. For example, a construction material type “brick” can be stored for the BIM object. The corresponding wall thickness and/or a construction material of the wall XYZ can be determined based on the building plan and entered in the BIM model S6. In this case, it suffices to adopt only the corner points of the wall and to connect them using lines. A texture for the known front side of the object can be optionally generated from the remaining points and stored together with the BIM object. In addition, certain properties and objects which can be found in descriptions in the plan can be added. For example, windows, pipes or steel girders which, according to the 2D building plan, are contained in the corresponding wall can be added. Certain assumptions (for example standardized lengths) are made for the extent of these objects in the z direction. In addition, these objects can also be used as the starting point for advanced modeling.

FIG. 4 schematically shows an exemplary embodiment of an aspect of the method for generating a building information model.

A variant of the method step of comparing S3 the three-dimensional building data 3DD with the building plan, which is shown by way of example in FIGS. 1 to 3, is schematically outlined.

A horizontal structure is determined based on the three-dimensional building data 3DD which, for example as individual data points or scan points SCP, form a point cloud. In this case, the horizontal structure is determined based on the three-dimensional building data 3DD by virtue of data points/scan points SCP lying one above the other in the vertical direction being counted.

The data or scan points SCP lying one above the other can be counted in a similar manner to an imaginary precipitation calculation. In this case, the scan points fall to the ground like (imaginary) precipitation in the algorithm and are collected there by imaginary measuring beakers. If adjacent measuring beakers contain the same number of scan points substantially within a predefined measurement inaccuracy, it is derived therefrom that they belong to the same element, for example a room-high wall or an item of furniture. In other words, the scan points SCP lying one above the other in the z direction are added and the number of scan points in the horizontal direction is compared in each case.

This makes it possible to determine, for example, a region of the floor 201, of the wall 202 and/or of an item of furniture 203. Horizontally adjacent scan points are taken into account when determining such a building object.

If the adjacent data/scan points SCP in the vertical direction have a number that corresponds substantially and/or within a predefined tolerance range, they may be horizontally connected to one another using a line. A line or another graphical primitive is produced in this manner. This line which has been produced can then be compared with a line of a two-dimensional building plan in order to determine building objects in the building plan which correspond to the three-dimensional building data.

FIG. 5 shows a schematic block diagram of an exemplary embodiment of a system 100 according to embodiments of the invention for generating a building information model for a building G.

The system 100 comprises an interface 101, a scanning unit 102, a comparison unit 103, a detection unit 104, a model generator 105, an integration unit 106 and an output unit 107. The individual units or components of the system 100 are connected to one another, in particular, via communication connections, that is to say they can interchange data with one another.

The system 100 may comprise, in particular, at least one processor and may comprise, in particular, hardware and software components. In particular, the respective units may each comprise interfaces and/or a storage unit in order to process data, for example building data.

The interface 101 is set up in such a way as to read in a two-dimensional building plan 2DP of the building G, for example a floor plan or an electrical installation plan. The two-dimensional building plan comprises building objects and building object data assigned to the building objects. The building plan is in the form of a file or a data structure. The building objects in the building plan are, for example, schematic two-dimensional images or digital representations of real/physical building objects in the real building.

The scanning unit 102 is set up in such a way as to acquire a three-dimensional building data of at least a part of the building. The scanning unit 102 may be a scanner/laser scanner, for example. The scanning unit 102 scans at least a subregion of the building and provides data points in a Cartesian coordinate system which, as a point cloud, reproduce a three-dimensional view of the scanned subregion. The scanning unit 102 may be mobile, in particular, wherein it is connected to the other units of the system 100, for example, via a wireless communication connection for transmitting the acquired three-dimensional building data. The scanning unit 102 can therefore move along a route/trajectory determined based on the building plan, for example, and can scan the building G in this manner.

The comparison unit 103 is set up in such a way as to compare the three-dimensional building data 3DD with the building plan 2DP, wherein at least a subregion of the building plan at the position of the scanning unit is evaluated. In this case, in particular, the three-dimensional building data are compared with the two-dimensional data of the building plan, as explained, by way of example, with reference to FIG. 3. Furthermore, the comparison unit 103 is set up to output corresponding comparison data CD as the result of this comparison. The comparison data CD may include a correlation or a deviation of the three-dimensional building data with or from the building plan. This data comparison is carried out for the data of the building plan at the position and/or in the environment of the scanning unit 102. In other words, only data of the building plan in a predefined region at the current position of the scanning unit 102 are considered for the comparison.

The detection unit 104 is set up in such a way as to detect at least one building object OBJ in the building plan based on the comparison data CD and to output building object data OBJD assigned to the detected building object and/or the building object OBJ. If the comparison data CD include a discrepancy between the three-dimensional building data 3DD and the building plan 2DP, the system 100 may also comprise an object generation unit (not shown) which is set up to generate a building object and corresponding building object data depending on the three-dimensional building data and to make them available to the integration unit.

The model generator 105 is set up in such a way as to generate the building information model from the three-dimensional building data 3DD. The model generator 105 therefore creates a 3D model from the acquired three-dimensional building data acquired by the scanning unit 103.

The integration unit 106 is set up in such a way as to integrate the detected building object OBJ and the assigned building object data OBJD into the building information model BIM. For example, “integration” may be understood to mean reading in, storing and/or linking to the three-dimensional model.

The output unit 107 is set up in such a way as to output the generated building information model in order to work on the building. The building G may be worked on, for example renovated, with the aid of the building information model BIM, for example.

Although the present invention has been disclosed in the form of preferred embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements.

1. A method for generating a building information model for working on a building, comprising the following method steps:
a) reading in a two-dimensional, digitized building plan of the building, wherein the building plan comprises building objects and building object data assigned to the building objects,
b) acquiring three-dimensional building data of at least a part of the building by means of a scanning unit,
c) comparing the three-dimensional building data with the building plan, wherein at least a subregion of the building plan at a position of the scanning unit is evaluated, and outputting comparison data,
d) detecting at least one building object in the building plan based on the comparison data and outputting building object data assigned to the detected building object,
e) generating the building information model from the three-dimensional building data,
f) integrating the detected building object and the assigned building object data into the building information model,
and
g) outputting the generated building information model in order to work on the building.

2. The method as claimed in claim 1, wherein the three-dimensional building data are acquired by scanning the building along a trajectory defined in the building plan by means of the scanning unit.

3. The method as claimed in claim 1, wherein a starting point is determined based on the building plan and the three-dimensional building data are acquired proceeding from this starting point.

4. The method as claimed in claim 1, wherein method steps b) to d) are repeated after predefined time steps.

5. The method as claimed in claim 1, wherein method steps b) to d) are repeated after detection of a building object.

6. The method as claimed in claim 1, wherein a deviation of the three-dimensional building data from the building plan is detected based on the comparison data.

7. The method as claimed in claim 6, wherein, if a deviation is identified, a building object and corresponding building object data are generated depending on the three-dimensional building data and integrated into the building information model.

8. The method as claimed in claim 1, wherein the method step of comparing the three-dimensional building data with the building plan comprises the following substeps:
determining a horizontal structure based on the three-dimensional building data,
generating a first line based on the horizontal structure,
comparing the first line with lines of the building plan, wherein the first line is assigned to a second line of the building plan,
and
correcting the spatial coordinates of the three-dimensional building data, assigned to the first line, depending on the position of the second line.

9. The method as claimed in claim 8, wherein the at least one building object is detected based on the second line in the building plan.

10. The method as claimed in claim 8, wherein the horizontal structure is detected based on the three-dimensional building data by virtue of data points lying one above the other in the vertical direction being counted and being connected horizontally to adjacent data points along the respectively topmost data point provided that the adjacent data points in the vertical direction have a substantially corresponding number.

11. The method as claimed in claim 1, wherein the method step of comparing the three-dimensional building data with the building plan is carried out by means of a machine learning model trained for this purpose.

12. The method as claimed in claim 1, wherein the building plan is a floor plan or an electrical installation plan.

13. The method as claimed in claim 1, wherein the building information model is a BIM model.

14. A system for generating a building information model for working on a building, comprising:
an interface that is set up in such a way as to read in a two-dimensional building plan of the building, wherein the two-dimensional building plan comprises building objects and building object data assigned to the building objects,
a scanning unit that is set up in such a way as to acquire three-dimensional building data of at least a part of the building,
a comparison unit that is set up in such a way as to compare the three-dimensional building data with the building plan, wherein at least a subregion of the building plan at the position of the scanning unit is evaluated, and to output comparison data,
a detection unit that is set up in such a way as to detect at least one building object in the building plan based on the comparison data and to output building object data assigned to the detected building object,
a model generator that is set up in such a way as to generate the building information model from the three-dimensional building data,
an integration unit that is set up in such a way as to integrate the detected building object and the assigned building object data into the building information model,
and
an output unit that is set up in such a way as to output the generated building information model in order to work on the building.

15. A computer program product, comprising a computer readable hardware storage device having computer readable program code stored therein, said program code executable by a processor of a computer system to implement a method, which is loaded directly into a programmable computer, comprising program code parts which are suitable for carrying out the steps of the method as claimed in claim 1.
